(19) United States
(12) Patent Application Publication
(10) Pub. No.: US 2006/0038706 A1
(43) Pub. Date: Feb. 23, 2006

(54) Sealed keyboard

(76) Inventors: Nicolas Berthou, Aze (FR); Gilles Raymond, Romilly Du Perche (FR); Guillaume Detre, Vendome (FR); David Politzer, Tours (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/528,033

(22) PCT Filed: Oct. 3, 2003
(86) PCT No.: PCT/FR03/02911

§ 371 Date: Mar. 16, 2005

(30) Foreign Application Priority Data
Oct. 18, 2002 (FR) 02/13006

(51) Int. Cl. H03M 11/00

(52) U.S. Cl. 341/22

(57) ABSTRACT

The invention relates to the sealing of a keyboard. The invention is particularly, but not exclusively, applicable in a keyboard fitted on an aircraft instrument panel. The keyboard comprises at least one switch, a rigid key allowing an operator to operate the switch, a front face comprising an opening traversed by the rigid key, and sealing means preventing particles from penetrating between the rigid key and the opening. According to the invention, the sealing means comprise a flexible membrane traversed by the rigid key, attached to the key and to the front face.

The invention relates to the sealing of a keyboard. The invention is particularly, but not exclusively, applicable to a keyboard fitted on an aircraft instrument panel.

A keyboard usually has at least one switch surmounted by a rigid key. An operator presses on the top of the rigid key to operate the switch. The switch and the rigid key form mobile parts that are sensitive to the penetration of solid or liquid particles likely to impair the operation of the keyboard. The presence of these particles requires maintenance of the keyboard either by cleaning or by changing the damaged mobile parts. To remedy this problem, improvements have been made to the sealing of keyboards by providing a flexible film either between the switch and the rigid key, or above the rigid key. A keyboard usually comprises several switches each associated with a rigid key. The flexible film then covers all the switches or all the rigid keys. The flexibility of the film is necessary to ensure that the film deforms during operations of the switch or switches by an operator.

The deformation of the film has a disadvantage for the operator. More precisely, the film introduces a flexible element between the finger of the operator and the switch. This flexible element adversely affects the precision of control of the switch by the operator. For the operator, it is preferable to have only a rigid element between his finger and the switch. If the flexible element is disposed between the switch and an associated rigid key, the flexible element provides an additional movement of the rigid key when an operator presses on the key. The same applies to a flexible film covering the key. The finger of the operator then partially indents the flexible element. Precision of control of the switch is, for example, necessary on an aircraft instrument panel. The pilot using the keyboard of this instrument panel must be able to enter data relating to the conduct of the aircraft with a perfect reliability and the presence of a flexible element reduces this reliability.

The object of the invention is to alleviate this fault by proposing a keyboard in which no flexible element is placed between the finger of the operator and the switch while ensuring a seal comparable to that obtained with a continuous film covering the whole keyboard.

Accordingly, the subject of the invention is a keyboard comprising at least one switch, a rigid key allowing an operator to operate the switch, a front face comprising an opening traversed by the rigid key, and sealing means preventing particles from penetrating between the rigid key and the opening, characterized in that the sealing means comprise a flexible membrane traversed by the rigid key, attached to the key and to the front face.

It is well understood that the invention is not limited to a single switch surmounted by a rigid key. The invention is particularly well suited to a keyboard comprising a large number of switches each surmounted by a rigid key.

The invention will be better understood and other advantages will appear on reading the detailed description of an embodiment given as an example, the description being illustrated by the attached drawing in which:

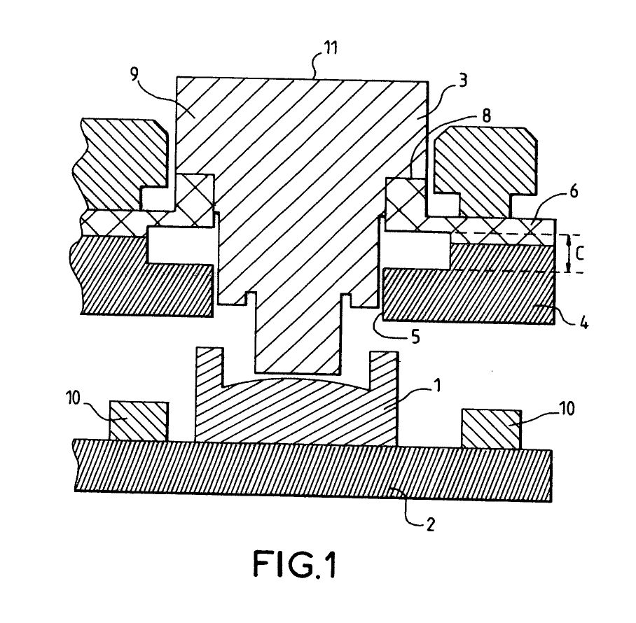

FIG. 1 shows an exemplary embodiment of a keyboard according to the invention.

The keyboard shown in FIG. 1 comprises a switch 1 placed on a support plate 2. The support plate 2 is, for example, a printed circuit board providing electrical connections necessary for the operation of the switch 1. The support plate 2 may support several switches 1. The keyboard also comprises a rigid key 3 surmounting the switch 1, and allowing an operator to operate the switch 1. The material of the rigid key 3 is selected to prevent any deformation of the key 3 when the operator presses the key 3. The keyboard also comprises a front face 4 comprising an opening 5 traversed by the rigid key 3. Sealing means prevent particles situated on the outside of the keyboard, that is to say where the operator is situated, from penetrating between the rigid key 3 and the front face 4 via the space left free between the rigid key 3 and the opening 5. These particles may consist of granules of dust present in the ambient air or of liquids likely to be spilt over the keyboard by the operator.

The sealing means comprise a flexible membrane 6 traversed by the rigid key 3. The flexible membrane 6 is attached both to the front face 4 and to the rigid key 3 advantageously by bonding.

Advantageously, keyboards comprise means of limiting the travel of the rigid key 3 relative to the front face 4. More precisely, these means are used to prevent too great a pressure of the operator on the rigid key 3 from damaging the switch 1.

The limiting means comprise for example a shoulder 8 belonging to the rigid key 3. The shoulder 8 forms a portion 9 of the rigid key 3, a portion that cannot penetrate inside the keyboard through the opening 5. The inside of the keyboard is the space lying between the support plate 2 and the front face 4. The switch 1 is situated inside the keyboard. Thus, when the operator presses on the rigid key 3, it travels inward until the shoulder 8 butts against the front face 4.

Advantageously, the shoulder 8 is used to attach the flexible membrane 6 and the shoulder 8 comes into contact with the front face 4 via the flexible membrane 6, which softens a possible impact between the rigid key 3 and the front face 4 when these two elements come into contact with one another. Softening the impact is used to reduce the noise level when the operator operates the keyboard. In FIG. 1, the travel of the key is shown by reference C.

Advantageously, the rigid key 3 is transparent and the keyboard comprises means of lighting the rigid key 3 from inside the keyboard. These lighting means comprise, for example, light emitting diodes 10 attached to the support plate 2 inside the keyboard. The light emitting diodes are, for example, powered by tracks printed on the support plate 2.

The fact, thanks to the invention, that a continuous flexible film covering the whole keyboard is dispensed with allows the rigid key 3 to be lit via the inside of the keyboard in the best conditions. More precisely, thanks to the invention, the lighting passes through only one medium other than the air, that is the rigid key 3. In the prior art, light rays had to pass through both the rigid key 3 and the flexible film, which, as a consequence, had to be transparent. Thanks to the invention, it is no longer necessary for the flexible film 6 to be transparent, which makes it possible to broaden the choice of the materials of which it is made.

The top 11 of the rigid key 3 may be covered with an opaque material such as for example paint, then the opaque material may be removed locally, for example by engraving. The engraving may, for example, have the shape of one or more alphanumeric characters. The lighting will thus be used to view this or these characters.

1. A keyboard comprising;
a switch,
a rigid key allowing an operator to operate the switch, a front face having an opening traversed by the rigid key, and
sealing means preventing particles from penetrating between the rigid key and the opening,
wherein the sealing means comprise a flexible membrane traversed by the rigid key, attached to the key and to the front face.

2. The keyboard as claimed in claim 1, wherein the flexible membrane is attached to the rigid key and to the front face by bonding.

3. The keyboard as claimed in claim 1, wherein it comprises means of limiting the travel of the rigid key relative to the front face.

4. The keyboard as claimed in claim 3, wherein the limitation means comprise a shoulder of the rigid key, and in that the shoulder is capable of butting against the front face when the operator presses on the rigid key.

5. The keyboard as claimed in claim 4, wherein the flexible membrane is attached to the rigid key on the shoulder.

6. The keyboard as claimed in claim 1, wherein it comprises means of lighting the rigid key via the inside of the keyboard, and in that the rigid key is transparent.

7. The keyboard as claimed in claim 2, wherein it comprises means of limiting the travel of the rigid key relative to the front face.

8. The keyboard as claimed in claim 2, wherein it comprises means of lighting the rigid key via the inside of the keyboard, and in that the rigid key is transparent.

9. The keyboard as claimed in claim 3, wherein it comprises means of lighting the rigid key via the inside of the keyboard, and in that the rigid key is transparent.

10. The keyboard as claimed in claim 4, wherein it comprises means of lighting the rigid key via the inside of the keyboard, and in that the rigid key is transparent.

11. The keyboard as claimed in claim 5, wherein it comprises means of lighting the rigid key via the inside of the keyboard, and in that the rigid key is transparent.
